(19) United States
(12) Patent Application Publication
(10) Pub. No.: US 2024/0027512 A1
(43) Pub. Date: Jan. 25, 2024

(54) MEASURING EQUIPMENT AND MEASURING METHOD FOR MEASURING ELECTRONIC PROPERTIES AND OPTICAL PROPERTIES

(71) Applicant: Innolux Corporation, Miaoli County (TW)

(72) Inventors: Ker-Yih Kao, Miaoli County (TW); Kuang-Ming Fan, Miaoli County (TW); Wang-Chih Tsai, Miaoli County (TW); Chien-Li Lin, Miaoli County (TW)

(73) Assignee: Innolux Corporation, Miaoli County (TW)

(21) Appl. No.: 18/336,939

(22) Filed: Jun. 16, 2023

Related U.S. Application Data
(60) Provisional application No. 63/391,797, filed on Jul. 25, 2022.

(30) Foreign Application Priority Data
Apr. 17, 2023 (CN) 202310408522.4

(51) Int. Cl. G01R 31/26; G01N 21/84

(52) U.S. Cl. CPC G01R 31/2607; G01N 21/84

(57) ABSTRACT

A measuring equipment and a measuring method for measuring electronic properties and optical properties are disclosed. The measuring equipment is used to measure electronic and optical properties. The measuring equipment includes a test socket, a light-emitting element circuit, an optical device, a signal conversion circuit, and a control host. The test socket has measuring probes. The test socket tests the electronic properties of the semiconductor device through the measuring probes. The light-emitting element circuit has a light-emitting element. The optical device measures the optical properties of the light-emitting element. The signal conversion circuit converts the electronic properties to an electronic signal. The control host analyzes and stores the electronic signal and the optical properties.

### CROSS-REFERENCE TO RELATED APPLICATION

This application claims the priority benefits of U.S. provisional application Ser. No. 63/391,797, filed on Jul. 25, 2022, and China application serial no. 202310408522.4, filed on Apr. 17, 2023. The entirety of each of the above-mentioned patent applications is hereby incorporated by reference herein and made a part of this specification.

### BACKGROUND

### Technical Field

This disclosure relates to a measuring equipment and a measuring method, in particular to a measuring equipment and a measuring method for measuring electronic properties and optical properties.

### Description of Related Art

Current measuring equipment evaluates the quality of a semiconductor device based on electronic properties of the semiconductor device such as voltage or current. If a semiconductor device is used as a driving device for a light-emitting element, when the measuring equipment determines that the electronic properties of the semiconductor device exceeds a specification, the semiconductor device is often fed to another measurement station to drive a standard light-emitting element, and the semiconductor device is determined to be acceptable or not based on optical properties of the standard light-emitting element being driven.

For example, when the electronic properties of the semiconductor device exceeds an electrical specification and the optical properties generated by the standard light-emitting element driven by the semiconductor device meets a light emission specification, the semiconductor device is determined to be acceptable. When the electronic properties of the semiconductor device exceeds the electrical specification and the optical properties generated by the standard light-emitting element driven by the semiconductor device exceeds the light emission specification, the semiconductor device is determined to be scrapped or returned.

It should be noted that in the above test process, when the measuring equipment determines that the electronic properties of the semiconductor device exceeds the specification, the semiconductor device will be fed to another measuring equipment to test and drive the standard light-emitting element. The above test process must be performed using two different sets of equipment. Therefore, the costs of equipment and time for testing will increase.

### SUMMARY

The disclosure is directed to a measuring equipment and a measuring method for measuring electronic properties and optical properties, capable of reducing costs of equipment and time for testing.

According to an embodiment of the disclosure, the measuring equipment is used to measure electronic properties and optical properties. The measuring equipment includes a test socket, a light-emitting element circuit, an optical device, a signal conversion circuit, and a control host. The test socket has at least one measuring probe. The test socket tests the electronic properties of a semiconductor device through the at least one measuring probe to generate an electronic signal. The light-emitting element circuit has a light-emitting element. The test socket is coupled to the light-emitting element. The optical device measures the optical properties of the light-emitting element. The signal conversion circuit converts a format of the electronic signal. The control host analyzes and stores the electronic signal and the optical properties.

According to an embodiment of the disclosure, the measuring method includes the followings. A semiconductor device is provided on a test socket so that the test socket utilizes at least one measuring probe to test electronic properties of the semiconductor device. The test socket is coupled to a light-emitting element circuit, in which the light-emitting element circuit has a light-emitting element. An optical device is provided to measure optical properties of the light-emitting element. A signal conversion circuit is provided to convert the electronic properties to an electronic signal. A control host is provided to analyze and store the electronic signal and the optical properties, and classify the semiconductor device.

Based on the above, the measuring equipment and the measuring method of the disclosure may test the electronic properties of the semiconductor device and obtain the optical properties when the light-emitting element is driven. In this way, the measuring equipment and the measuring method may reduce the costs of equipment and time for testing.

To make the aforementioned more comprehensive, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a measuring equipment according to a first embodiment of the disclosure.

FIG. 2 is a schematic diagram of operation according to the first embodiment.

FIG. 3 is a schematic diagram of a measuring equipment according to a second embodiment of the disclosure.

FIG. 4 is a schematic diagram of a measuring equipment according to a third embodiment of the disclosure.

FIG. 5 is a schematic diagram of a measuring equipment according to a fourth embodiment of the disclosure.

FIG. 6 is a graph of characteristics of a semiconductor device according to an embodiment of the disclosure.

FIG. 7 is a flowchart of a measuring method according to an embodiment of the disclosure.

FIG. 8 is a schematic diagram of a measuring system according to an embodiment of the disclosure.

### DESCRIPTION OF THE EMBODIMENTS

The disclosure can be understood by referring to the following detailed description taken in conjunction with the accompanying drawings as described below. It should be noted that, for purposes of clarity and easy understanding by readers, each drawing of the disclosure depicts a part of an electronic device, and some components in each drawing may not be drawn to scale. Furthermore, the number and size of each device depicted in the drawings is illustrative only and not intended to limit the scope of the disclosure.

Certain terms are used throughout the description and the following claims to refer to specific components. As will be understood by those skilled in the art, electronic device manufacturers may refer to components by different names. This disclosure does not intend to distinguish between components that differ in name but not function. In the following description and in the claims, the terms “comprising”, “including” and “having” are used in an open-ended manner and should therefore be construed to mean “comprising but not limited to . . . ” Therefore, when the terms “comprising”, “including” and/or “having” are used in the description of the disclosure, it will indicate the existence of corresponding features, regions, steps, operations and/or components, but are not limited to the existence of one or more corresponding features, regions, steps, operations and/or components.

It should be understood that when a component is referred to as being “coupled to”, “connected to” or “conducted to” another component, the component may be directly connected to the other component and may directly establish an electrical connection, or there may be intermediate components between these components for relaying electrical connections (indirect electrical connections). In contrast, when a component is referred to as being “directly coupled to”, “directly conducted to”, or “directly connected to” another component, there are no intermediate components present.

Although terms such as first, second, third, etc. may be used to describe various constituent components, such constituent components are not limited by these terms. The terms are used only to distinguish a constituent component from other constituent components in the specification. A claim may not use the same terms, but may use the terms first, second, third, etc. relative to the order in which the components are required. Therefore, in the following description, the first component can be the second component in the claims.

The electronic device disclosed herein may include a display device, an antenna device, a sensing device, a light-emitting device, a touch display device, a curved display device, or a non-rectangular electronic device (free shape display), but is not limited thereto. The electronic device may include bendable or flexible electronic device. The electronic device may include, for example, liquid crystal, light-emitting diode, quantum dot (QD), fluorescence, phosphor, other suitable display media, or a combination of the above materials, but is not limited thereto. The light-emitting diode may, for example, include organic light-emitting diode (OLED), submillimeter light-emitting diode (mini LED), micro light-emitting diode (micro LED) or quantum dot light-emitting diode (quantum dot LED, may include QLED, QDLED), or other suitable materials, or a combination of the above, but is not limited thereto. The display device may, for example, include a spliced display device, but is not limited thereto. The antenna device may be, for example, a liquid crystal antenna or a varactor antenna, but is not limited thereto. The antenna device may include, for example, an antenna splicing device, but is not limited thereto. It should be noted that the electronic device can be any permutation and combination of the aforementioned, but is not limited thereto. In addition, the shape of the electronic device can be rectangular, circular, polygonal, with curved edges, or other suitable shapes. The electronic device may have peripheral systems such as a driving system, a control host, a light source system, to support a display device, an antenna device, or a splicing device, but the disclosure is not limited thereto. The sensing device may include a camera, an infrared sensor or a fingerprint sensor, etc., and the disclosure is not limited thereto. In some embodiments, the sensing device may further include a flashlight, an infrared (IR) light source, other sensors, electronic components, or a combination thereof, but is not limited thereto.

In the disclosure, the embodiments use “pixel” or “pixel unit” as a unit for describing a specific region including at least one functional circuit for at least one specific function. The region of a “pixel” depends on the unit used to provide a particular function, adjacent pixels may share the same parts or wires, but may also contain specific parts of themselves. For example, adjacent pixels may share the same scan line or the same data line, but a pixel may also have its own transistor or capacitor.

It should be noted that technical features in different embodiments described below may be replaced, rearranged or mixed with each other to form another embodiment without departing from the spirit of the disclosure.

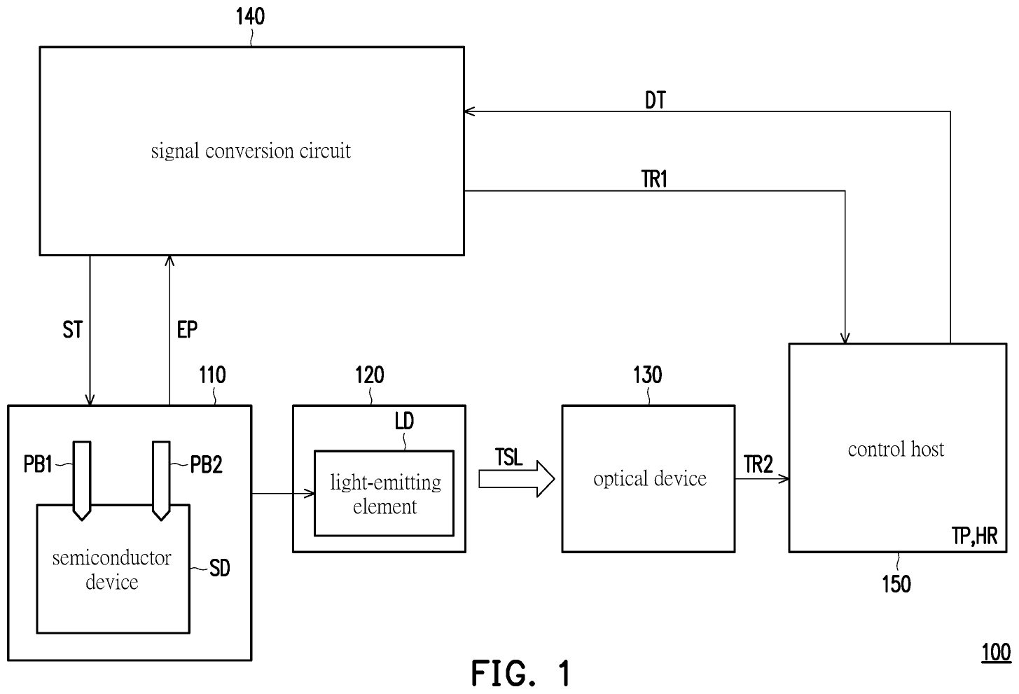

Referring to FIG. 1, FIG. 1 is a schematic diagram of a measuring equipment according to a first embodiment of the disclosure. In this embodiment, a measuring equipment 100 is used to measure electronic properties EP and optical properties TR2. The measuring equipment 100 includes a test socket 110, a light-emitting element circuit 120, an optical device 130, a signal conversion circuit 140, and a control host 150. The test socket 110 has a measuring probe PB1 and a measuring probe PB2. The test socket 110 tests the electronic properties EP of a semiconductor device SD through the measuring probes PB1 and PB2. The electronic properties EP of the semiconductor device SD may be a voltage signal, a current signal, or an impedance value generated by the semiconductor device SD based on a test pattern TP, but the disclosure is not limited thereto. In this embodiment, the semiconductor device SD is a device under test (DUT).

In this embodiment, the light-emitting element circuit 120 has a light-emitting element LD. The test socket 110 is coupled to the light-emitting element LD. In this embodiment, the semiconductor device SD may be a driving circuit for driving the light-emitting element LD. The light-emitting element LD includes at least one light-emitting diode in any form, but the disclosure is not limited thereto.

In this embodiment, the optical device 130 measures the optical properties TR2 of the light-emitting element LD. For example, in this embodiment, the optical device 130 receives test light TSL provided by the light-emitting element LD, and measures the optical properties TR2 of the light-emitting element LD. The optical device 130 includes at least one of a charge-coupled device (CCD), an illuminometer, a spectrophotometer, a spectroradiometer, and an image capture equipment, but the disclosure is not limited thereto. For example, in this embodiment, during a testing process, the semiconductor device SD may drive the light-emitting element LD through the test socket 110, so that the light-emitting element LD provides the test light TSL. The optical device 130 measures the test light TSL of the light-emitting element LD to obtain the optical properties TR2. It can be known that the optical properties TR2 are associated with a driving result of the semiconductor device SD on the light-emitting element LD.

In this embodiment, the signal conversion circuit 140 is coupled to the test socket 110. The signal conversion circuit 140 converts the electronic properties EP to an electronic signal TR1. For example, the signal conversion circuit 140 converts the electronic properties EP having an analog format to the electronic signal TR1 having a digital format, and provides the electronic signal TR1 having the digital format to the control host 150.

In this embodiment, the control host 150 is coupled to the optical device 130 and the signal conversion circuit 140. The control host 150 receives the electronic signal TR1 and the optical properties TR2. The control host 150 analyzes the electronic signal TR1 and the optical properties TR2, and stores the electronic signal TR1 and the optical properties TR2. In addition, the electronic signal TR1 and the optical properties TR2 are stored to become a production history HR of the semiconductor device SD. The production history HR may be a quality file of the semiconductor device SD of the same lot, but this disclosure is not limited thereto.

The control host 150 of the measuring equipment 100 obtains the electronic signal TR1 and the optical properties TR2. For example, the control host 150 classifies the semiconductor device SD according to the electronic signal TR1 and the optical properties TR2. When the electronic signal TR1 of the semiconductor device SD meets an electrical specification, the control host 150 determines that the semiconductor device SD passes. When the electronic signal TR1 of the semiconductor device SD exceeds the electrical specification and the optical properties TR2 meets a light emission specification, the control host 150 still determines that the semiconductor device SD passes, but the semiconductor device SD is marked to distinguish the semiconductor device SD from the aforementioned situation where the electronic signal TR1 of the semiconductor device SD meets the electrical specification, the control host 150 determines that the semiconductor device SD passes. When the electronic signal TR1 exceeds the electrical specification and the optical properties TR2 exceed the light emission specification, the control host 150 determines that the semiconductor device SD is unqualified (NG), and the electronic signal TR1 and the optical properties TR2 may be stored to become the production history HR. It should be noted that the measuring equipment 100 may obtain the electronic signal TR1 for testing the semiconductor device SD and the optical properties TR2 of the light-emitting element LD driven by the semiconductor device SD. In this way, the measuring equipment 100 may reduce costs of equipment and time for testing.

In this embodiment, the control host 150 is, for example, an electronic device including an operation interface. The control host 150 is operated to create the test pattern TP. The control host 150 generates test data DT according to the test pattern TP, and provides the test data DT to the signal conversion circuit 140. The signal conversion circuit 140 converts the test data DT to a test signal ST. Further, the signal conversion circuit 140 converts the test data DT having a digital format to the test signal ST having an analog format. The signal conversion circuit 140 provides the test signal ST to the test socket 110. Thus, the test socket 110 tests the semiconductor device SD based on the test signal ST. During the test, the semiconductor device SD generates the electronic properties EP corresponding to the test pattern TP based on the test signal ST.

In some embodiments, the light-emitting element LD may be a device under test. The measuring equipment 100 may measure the light-emitting element LD. Further, the measuring equipment 100 controls the semiconductor device SD through the test socket 110 to drive the light-emitting element LD. The optical device 130 receives the test light TSL provided by the light-emitting element LD and measures the optical properties TR2 of the light-emitting element LD driven by the semiconductor device SD.

In some embodiments, the semiconductor device SD is an active or passive device, such as a varactor diode for a varactor antenna. Thus, the measuring equipment 100 controls the semiconductor device SD through the test socket 110, so that the semiconductor device SD provides the test data DT corresponding to the test pattern TP.

This embodiment takes two measuring probes PB1 and PB2 as an example. A number of the measuring probe disclosed in this disclosure may be one or more. The number of the measuring probe disclosed in this disclosure is not limited to this embodiment.

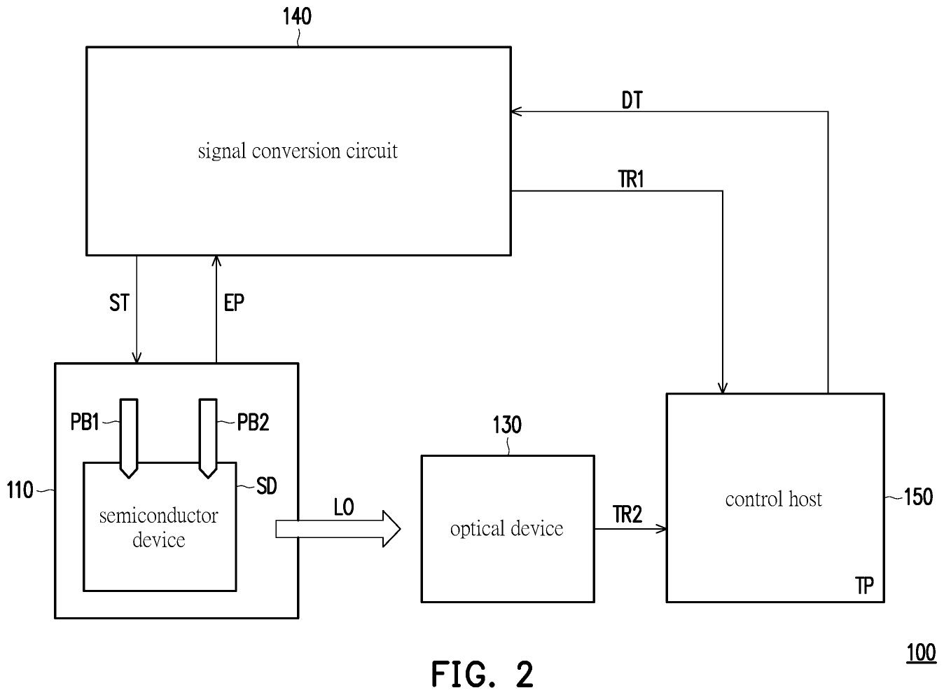

Referring to FIG. 2, FIG. 2 is a schematic diagram of operation according to the first embodiment. In this embodiment, the semiconductor device SD may be a device having a light-emitting function. Thus, the measuring equipment 100 controls the semiconductor device SD through the test socket 110, so that the semiconductor device SD provides output light LO corresponding to the test pattern TP. The optical device 130 measures the output light LO provided by the semiconductor device SD and the optical properties TR2 of the output light LO.

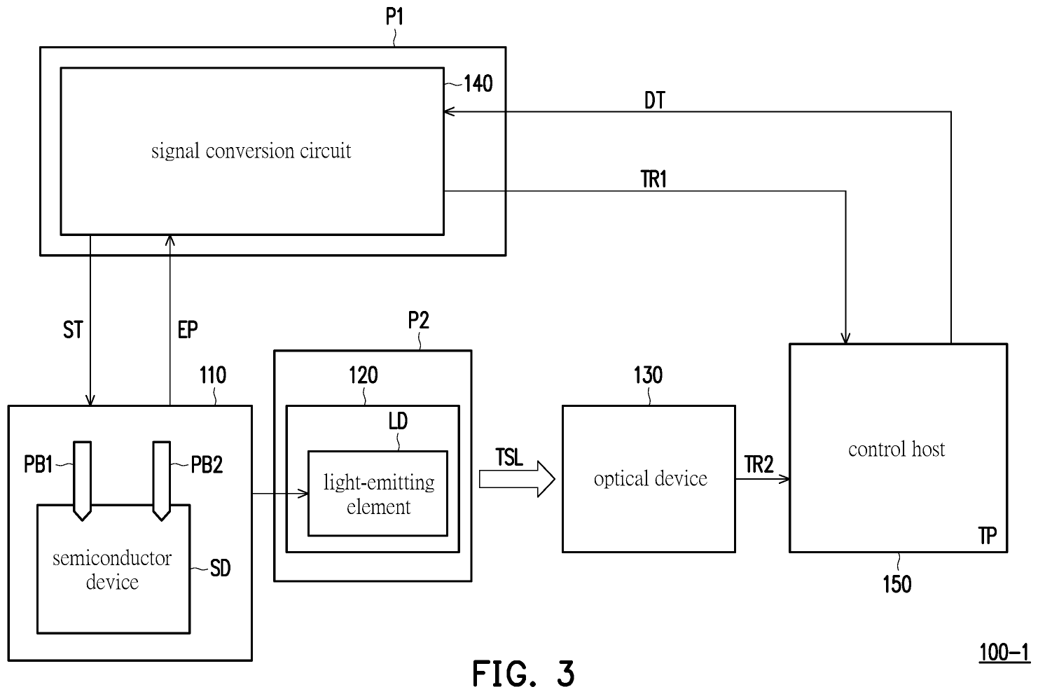

Referring to FIG. 3, FIG. 3 is a schematic diagram of a measuring equipment according to a second embodiment of the disclosure. In this embodiment, a measuring equipment 100-1 includes a test socket 110, a light-emitting element circuit 120, an optical device 130, a signal conversion circuit 140, and a control host 150. The cooperative implementation of the test socket 110, the light-emitting element circuit 120, the optical device 130, the signal conversion circuit 140, and the control host 150 has been clearly described in the embodiment of FIG. 1, and therefore will not be repeated in the following. In this embodiment, the signal conversion circuit 140 is disposed on a first circuit board P1. The light-emitting element circuit 120 is disposed on a second circuit board P2. The first circuit board P1 is electrically connected to the second circuit board P2. In this embodiment, the signal conversion circuit 140 may contact the light-emitting element circuit 120 through the electrical connection between the first circuit board P1 and the second circuit board P2, so that the light-emitting element circuit 120 is enabled. Thus, the light-emitting element LD may provide the test light TSL in response to the driving of the semiconductor device SD.

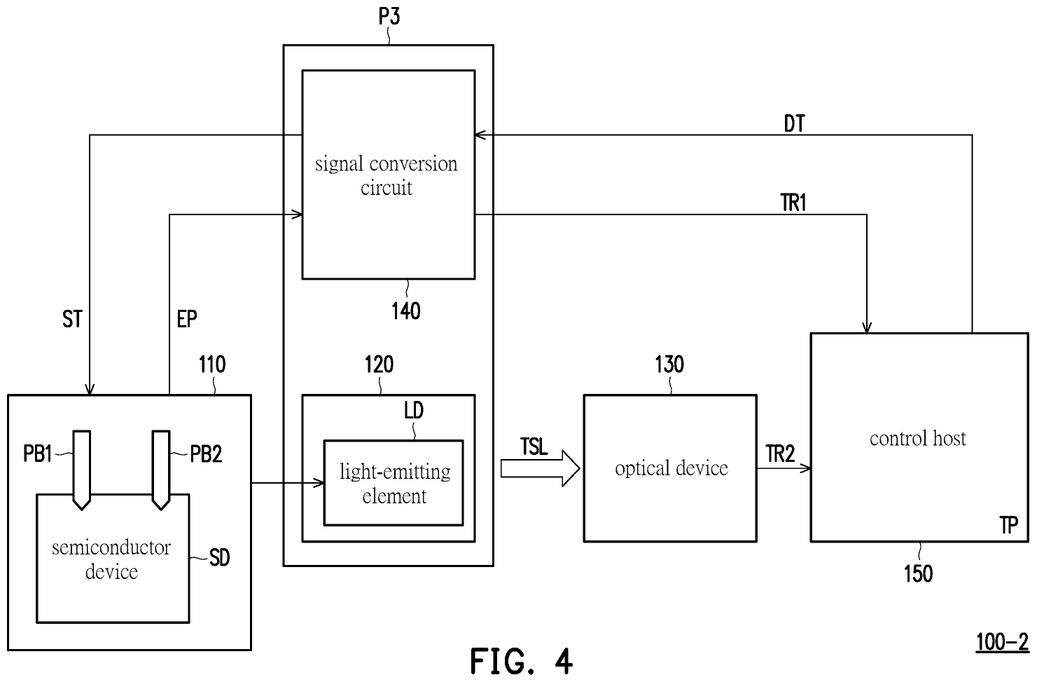

Referring to FIG. 4, FIG. 4 is a schematic diagram of a measuring equipment according to a third embodiment of the disclosure. In this embodiment, a measuring equipment 100-2 includes a test socket 110, a light-emitting element circuit 120, an optical device 130, a signal conversion circuit 140, and a control host 150. The cooperative implementation of the test socket 110, the light-emitting element circuit 120, the optical device 130, the signal conversion circuit 140, and the control host 150 has been clearly described in the embodiment of FIG. 1, and therefore will not be repeated in the following. The signal conversion circuit 140 and the light-emitting element circuit 120 are integrated into a same integrated circuit board P3.

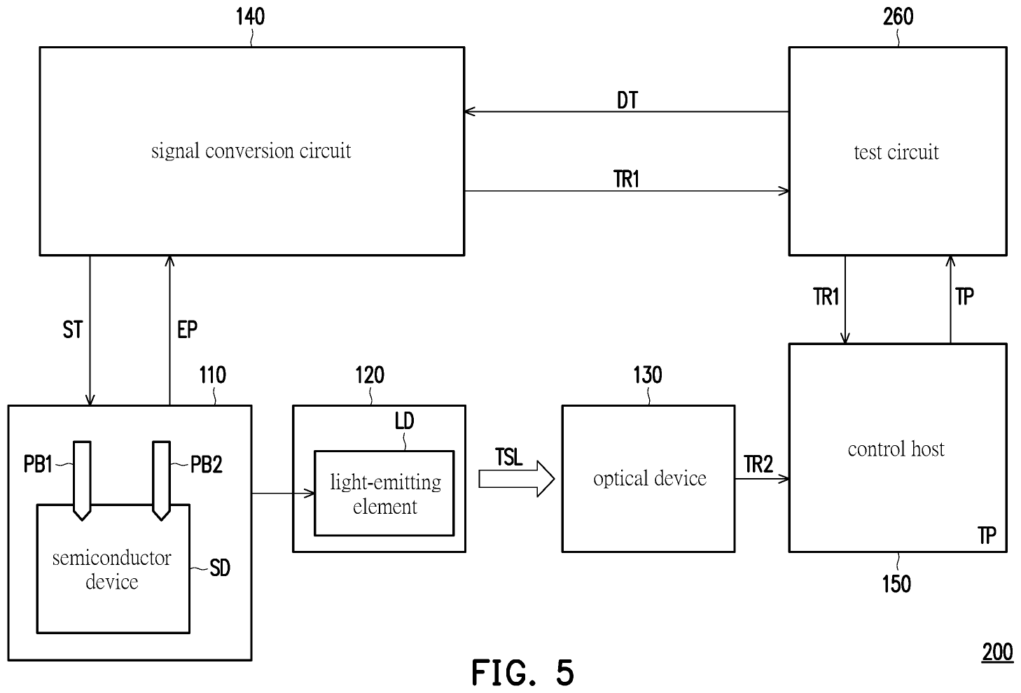

Referring to FIG. 5, FIG. 5 is a schematic diagram of a measuring equipment according to a fourth embodiment of the disclosure. In this embodiment, a measuring equipment 200 includes a test socket 110, a light-emitting element circuit 120, an optical device 130, a signal conversion circuit 140, a control host 150, and a test circuit 260. The test circuit 260 is coupled to the control host 150 and the signal conversion circuit 140. The test circuit 260 receives the test pattern TP, generates the test data DT according to the test pattern TP, and provides the test data DT to the signal conversion circuit 140. In addition, the test circuit 260 may also transmit the electronic signal TR1 from the signal conversion circuit 140 to the control host 150.

In some embodiments, the signal conversion circuit 140 may provide the electronic signal TR1 to the control host 150.

In some embodiments, the test circuit 260 may be disposed inside the signal conversion circuit 140 or inside the control host 150.

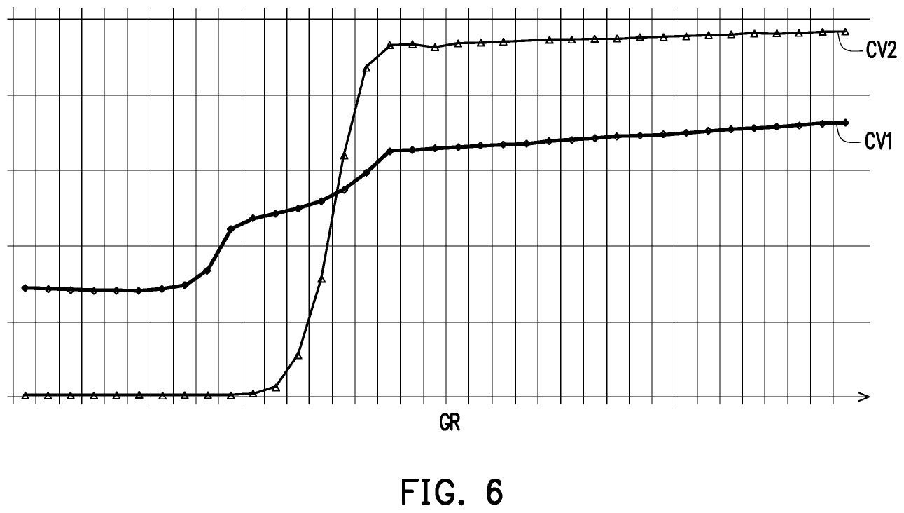

Referring to FIG. 1 and FIG. 6 at the same time, FIG. 6 is a graph of characteristics of a semiconductor device according to an embodiment of the disclosure. In this embodiment, the control host 150 may generate an electrical characteristic curve CV1 and a luminance characteristic curve CV2 of the semiconductor device SD. Specifically, a horizontal axis in FIG. 6 is, for example, a gray scale value GR. The electrical characteristic curve CV1 shows a trend between the gray scale value GR and a driving voltage provided by the semiconductor device SD. The luminance characteristic curve CV2 shows a trend between the gray scale value GR and a luminance value of the test light TSL. The control host 150 stores the electronic signal TR1 and the optical properties TR2. The control host 150 generates the electrical characteristic curve CV1 according to electronic signal TR1, and generates the luminance characteristic curve CV2 according to the optical properties TR2.

In this embodiment, the control host 150 further analyzes the electrical characteristic curve CV1 and the luminance characteristic curve CV2 to observe the performance of the driving voltage and the luminance value. The control host 150 may determine whether the electrical characteristic curve CV1 meets the electrical specification of the semiconductor device SD based on the similarity between an electrical specification curve and the electrical characteristic curve CV1. The control host 150 may determine whether the luminance characteristic curve CV2 meets a driving specification of the semiconductor device SD based on the similarity between a luminance specification curve and the luminance characteristic curve CV2.

For example, when the electrical characteristic curve CV1 meets the electrical specification of the semiconductor device SD, the control host 150 determines that the semiconductor device SD passes. When the electrical characteristic curve CV1 does not meet the electrical specification of the semiconductor device SD, and the luminance characteristic curve CV2 meets the driving specification of the semiconductor device SD, this means that the driving of the semiconductor device SD does not cause a significant difference in the output of the light-emitting element LD. Thus, the control host 150 still determines that the semiconductor device SD passes, but the semiconductor device SD is marked to distinguish the semiconductor device SD from the situation where the electronic signal TR1 of the semiconductor device SD meets the electrical specification.

In addition, based on the electrical characteristic curve CV1 and the luminance characteristic curve CV2, the control host 150 also classifies the semiconductor device SD by the performance of the driving voltage and the luminance value of the semiconductor device SD.

When the electrical characteristic curve CV1 does not meet the electrical specification of the semiconductor device SD, and the luminance characteristic curve CV2 does not meet the driving specification of the semiconductor device SD, the control host 150 determines that the semiconductor device SD is unqualified (NG).

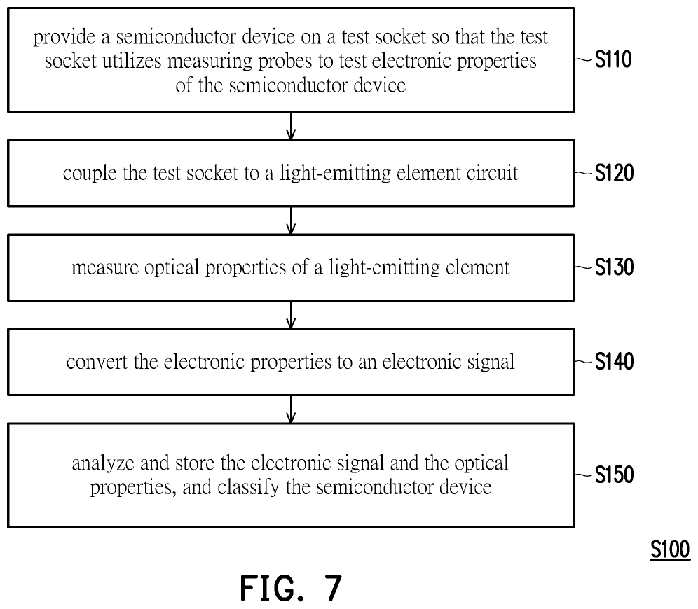

Referring to FIG. 1 and FIG. 7 at the same time, FIG. 7 is a flowchart of a measuring method according to an embodiment of the disclosure. In this embodiment, a measuring method S100 is applicable to the measuring equipment 100. The measuring method S100 includes steps S110 to S150. In step S110, the semiconductor device SD is provided on the test socket 100. The test socket 100 utilizes the measuring probe PB1 and the measuring probe PB2 to test the electronic properties EP of the semiconductor device SD. In step S120, the test socket 110 is coupled to the light-emitting element circuit 120. Thus, the semiconductor device SD may drive the light-emitting element LD located on the light-emitting element circuit 120 in step S120. In step S130, the optical device 130 is provided to measure the optical properties TR2 of the light-emitting element LD. In step S140, the signal conversion circuit 140 is provided to convert the electronic properties EP to the electronic signal TR1. In step S150, the control host 150 is provided to analyze and store the electronic signal TR1 and the optical properties TR2, and classify the semiconductor device SD. The implementation details of steps S110 to S150 have been clearly described in the embodiments of FIG. 1 to FIG. 6, and therefore will not be repeated in the following.

In this embodiment, the execution timing of step S140 may be adjusted. In some embodiments, step S140 may be performed before step S120. In some embodiments, step S140 may be performed before step S130.

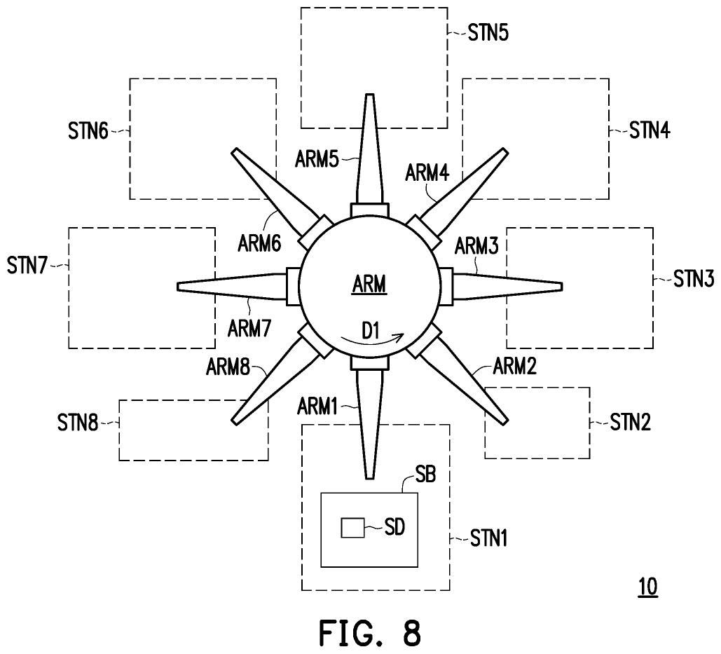

Referring to FIG. 1 and FIG. 8 at the same time, FIG. 8 is a schematic diagram of a measuring system according to an embodiment of the disclosure. In this embodiment, a measuring system 10 includes a mobile equipment ARM, workstations STN1 to STN5, and classification regions STN6 to STN8. The mobile equipment ARM includes eight robotic arms ARM1 to ARM8. In this embodiment, the robotic arms ARM1 to ARM8 are used to move the corresponding semiconductor devices, but the disclosure is not limited thereto.

This embodiment takes five workstations STN1 to STN5, three classification regions STN6 to STN8, and eight robotic arms ARM1 to ARM8 as an example. A number of the workstation and a number of the classification region disclosed in this disclosure may be multiple. A number of the robotic arm may be one or more in the disclosure. The disclosure is not limited to the number of the workstation, the number of the classification region, and the number of the robotic arm.

In this embodiment, the workstation STN1 is, for example, a material retrieving region. The robotic arm ARM1 of the mobile equipment ARM takes out the semiconductor device SD from a carrier board SB. The carrier board SB is, for example, a rigid substrate or a flexible substrate, and the disclosure is not limited thereto. The rigid substrate may be a glass substrate or a silicon substrate, and the disclosure is not limited thereto. The flexible substrate may be a plastic substrate or a polymer substrate, and the disclosure is not limited thereto. The mobile equipment ARM rotates in a direction D1 to allow the robotic arm ARM1 to feed the semiconductor device SD to the workstation STN2. In the workstation STN2, the semiconductor device SD is subjected to a positioning operation. The positioning operation is used to correct the position of the semiconductor device SD. After the positioning operation is completed, the robotic arm ARM1 is able to deliver the semiconductor device SD more precisely.

In the station STN2, after the positioning operation is completed, the robotic arm ARM1 removes the semiconductor device SD. The mobile equipment ARM rotates in the direction D1 to allow the robotic arm ARM1 to feed the semiconductor device SD to the workstation STN3. In the workstation STN3, an appearance inspection of the semiconductor device SD is carried out. The appearance inspection is used to confirm whether the semiconductor device SD is damaged or missing parts. After the appearance inspection is completed, the robotic arm ARM1 removes the semiconductor device SD. The mobile equipment ARM rotates in the direction D1 to allow the robotic arm ARM1 to feed the semiconductor device SD to the workstation STN4.

In this embodiment, the measuring equipment 100 is disposed at the workstation STN4. Therefore, the measuring system 10 may obtain the electronic signal TR1 associated with the semiconductor device SD and the optical properties TR2 generated by the light-emitting element LD driven by the semiconductor device SD in a single workstation STN4.

Generally, in the workstation STN4, the current measuring equipment is used to measure the electronic properties EP of the semiconductor device SD. When the electronic signal TR1 of the semiconductor device SD exceeds the electrical specification, the semiconductor device SD is moved to the workstation STN5 for the test of driving the light-emitting element LD. Therefore, in the above case, the measuring equipment 100 must use the workstation STN4 and the workstation STN5 to complete the measurement of the semiconductor device SD, in order to determine whether the semiconductor device SD is unqualified (NG). It should be noted that, in this embodiment, based on the measuring equipment 100, the measuring system 10 needs only a single workstation STN4 to determine whether the semiconductor device SD is unqualified (NG) or not. Thus, the workstation STN5 may be used for other inspections. The workstation STN5 may be equipped with another measuring equipment 100 to increase the inspection capacity of the measuring system 10.

In this embodiment, in the workstation STN4, the control host 150 notifies the mobile equipment ARM to move the semiconductor device SD to one of the classification regions STN6 to STN8 based on the electronic signal TR1 and the optical properties TR2 of the semiconductor device SD.

For example, in this embodiment, the control host 150 further classifies the qualified semiconductor device SD as a first-class specification or a second-class specification based on the electronic signal TR1 and the optical properties TR2 of the semiconductor device SD. If the control host 150 determines that the qualified semiconductor device SD is of the first-class specification, the control host 150 notifies the mobile equipment ARM to move the semiconductor device SD to the classification region STN6. As a result, the robotic arm ARM1 removes the semiconductor device SD. The mobile equipment ARM rotates in the direction D1 to allow the robotic arm ARM1 to feed the semiconductor device SD to the workstation STN6. If the control host 150 determines that the qualified semiconductor device SD is of the second-class specification, the control host 150 notifies the mobile equipment ARM to move the semiconductor device SD to the classification region STN7. As a result, the robotic arm ARM1 removes the semiconductor device SD. The mobile equipment ARM rotates in the direction D1 to allow the robotic arm ARM1 to feed the semiconductor device SD to the workstation STN7.

In addition, if the control host 150 determines that the semiconductor device SD is unqualified (NG), the control host 150 notifies the mobile equipment ARM to move the unqualified semiconductor device SD to the classification region STN8. As a result, the robotic arm ARM1 removes the semiconductor device SD. The mobile equipment ARM rotates in the direction D1 to allow the robotic arm ARM1 to feed the semiconductor device SD to the workstation STN5.

To sum up, the measuring equipment and the measuring method may test the electronic properties of the semiconductor device and obtain the optical properties when the light-emitting element is driven, and analyze and classify the semiconductor device according to the electronic signal and the optical properties corresponding to the electronic properties. In this way, the measuring equipment and the measuring method may reduce the costs of equipment and time for testing.

Finally, it should be noted that the above embodiments are only used to illustrate the technical solution of the disclosure, not to limit it; although the disclosure has been described in detail with reference to the foregoing embodiments, those skilled in the art should understand that it is still possible to modify the technical solutions described in the foregoing embodiments, or to replace some or all of the technical features thereof with equivalent ones. These modifications or replacements do not make the essence of the corresponding technical solutions deviate from the scope of the technical solutions of the embodiments of the disclosure.

What is claimed is:

1. A measuring equipment for measuring electronic properties and optical properties, wherein the measuring equipment comprises:
a test socket having at least one measuring probe, wherein the test socket tests the electronic properties of a semiconductor device through the at least one measuring probe;
a light-emitting element circuit having a light-emitting element, wherein the test socket is coupled to the light-emitting element;
an optical device configured to measure the optical properties of the light-emitting element;
a signal conversion circuit configured to convert the electronic properties to an electronic signal; and
a control host configured to analyze and store the electronic signal and the optical properties.

2. The measuring equipment according to claim 1, wherein the signal conversion circuit and the light-emitting element circuit are integrated into a same integrated circuit board.

3. The measuring equipment according to claim 1, wherein:
the signal conversion circuit is disposed on a first circuit board,
the light-emitting element circuit is disposed on a second circuit board, and the first circuit board is electrically connected to the second circuit board.

4. The measuring equipment according to claim 1, wherein the optical device comprises at least one of a charge-coupled device, an illuminometer, a spectrophotometer, a spectroradiometer, and an image capture equipment.

5. The measuring equipment according to claim 1, wherein the electronic signal and the optical properties are stored to become a production history of the semiconductor device.

6. The measuring equipment according to claim 1, wherein:
the semiconductor device drives the light-emitting element such that the light-emitting element provides test light, and
the optical device measures the test light of the light-emitting element to obtain the optical properties.

7. The measuring equipment according to claim 1, wherein the optical device measures output light provided by the semiconductor device.

8. The measuring equipment according to claim 1, wherein the signal conversion circuit converts the electronic properties having an analog format to the electronic signal having a digital format, and provides the electronic signal having the digital format to the control host.

9. The measuring equipment according to claim 1, wherein the control host classifies the semiconductor device based on the electronic signal and the optical properties.

10. The measuring equipment according to claim 1, wherein:
the control host creates a test pattern, generates test data according to the test pattern, and provides the test data to the signal conversion circuit,
the signal conversion circuit converts the test data to a test signal, and provides the test signal to the test socket, and
the test socket tests the semiconductor device based on the test signal.

11. The measuring equipment according to claim 1 further comprising:
a test circuit coupled to the control host and the signal conversion circuit, wherein the test circuit receives a test pattern from the control host, generates test data according to the test pattern, and provides the test data to the signal conversion circuit.

12. A measuring method comprising:
providing a semiconductor device on a test socket such that the test socket utilizes at least one measuring probe to test electronic properties of the semiconductor device;
coupling the test socket to a light-emitting element circuit, wherein the light-emitting element circuit has a light-emitting element;
providing an optical device to measure optical properties of the light-emitting element;
providing a signal conversion circuit to convert the electronic properties to an electronic signal; and
providing a control host to analyze and store the electronic signal and the optical properties, and classify the semiconductor device.

13. The measuring method according to claim 12, wherein the signal conversion circuit and the light-emitting element circuit are integrated into a same integrated circuit board.

14. The measuring method according to claim 12, wherein:
the signal conversion circuit is disposed on a first circuit board,
the light-emitting element circuit is disposed on a second circuit board, and the first circuit board is electrically connected to the second circuit board.

15. The measuring method according to claim 12, wherein providing the optical device to measure the optical properties of the light-emitting element comprises:
driving the light-emitting element by the semiconductor device such that the light-emitting element provides test light, and
measuring the test light of the light-emitting element by the optical device to obtain the optical properties.

16. The measuring method according to claim 12 further comprising:
measuring output light provided by the semiconductor device by the optical device.

17. The measuring method according to claim 12, wherein providing the signal conversion circuit to convert the electronic properties to the electronic signal comprises:
converting the electronic properties having an analog format to the electronic signal having a digital format by the signal conversion circuit, and providing the electronic signal having the digital format to the control host.

18. The measuring method according to claim 12, wherein analyzing and storing the electronic signal and the optical properties comprises:
storing the electronic signal and the optical properties to become a production history of the semiconductor device.

19. The measuring method according to claim 12 further comprising:
creating a test pattern by the control host, generating test data according to the test pattern, converting the test data to a test signal by the signal conversion circuit, and providing the test signal to the test socket, and
testing the semiconductor device based on the test signal by the test socket.

20. The measuring method according to claim 12 further comprising:
providing a test circuit to receive a test pattern of the control host; and
generating test data according to the test pattern by the test circuit, and providing the test data to the signal conversion circuit.
